(19) United States
(12) Patent Application Publication
(10) Pub. No.: US 2026/0343688 A1
(43) Pub. Date: Oct. 29, 2026

(54) SUSCEPTOR

(71) Applicant: MiCo Ceramics Ltd., Anseong-si (KR)

(72) Inventors: Chanwook Jang, Anseong-si (KR); Bogyeong Kim, Anseong-si (KR)

(21) Appl. No.: 19/645,382

(22) Filed: Apr. 13, 2026

(30) Foreign Application Priority Data
Apr. 29, 2025 (KR) 10-2025-0055892

(51) Int. Cl. H05B 6/10; H01C 7/22; H10P 72/76

(52) U.S. Cl. CPC H05B 6/105; H01C 7/22; H10P 72/7624

(57) ABSTRACT

Provided is a susceptor. The provided susceptor may include an insulating plate including a main heating element of a first layer and an auxiliary heating element of a second layer, which are stacked, wherein the main heating element is formed as a coil-type resistor connected between respective first terminal pairs and includes first arc portions at different radial positions and first folded portions connected between the first arc portions, wherein the auxiliary heating element is formed as a 2D wire-type resistor connected between respective second terminal pairs and includes second arc portions at different radial positions and second folded portions connected between the second arc portions, and wherein the main heating element and the auxiliary heating element are arranged without overlapping each other between layers across the insulating plate.

### CROSS-REFERENCE TO RELATED APPLICATIONS

This application is based on and claims priority under 35 U.S.C. 119 to Korean Patent Application No. 10-2025-0055892, filed on Apr. 29, 2025, in the Korean Intellectual Property Office, the disclosure of which is herein incorporated by reference in its entirety.

### BACKGROUND OF THE INVENTION

### 1. Field of the invention

The present disclosure relates to a susceptor and, in particular, to a susceptor with a heater pattern applied to improve temperature uniformity.

### 2. Description of the Prior Art

Typically, semiconductor devices or display devices are manufactured through a semiconductor process in which multiple thin film layers including dielectric and metal layers are sequentially stacked on a glass substrate, flexible substrate, or semiconductor wafer and then patterned. These thin film layers are sequentially deposited on the substrate through chemical vapor deposition (CVD) or physical vapor deposition (PVD) processes. CVD processes include low-pressure CVD (LPCVD), plasma-enhanced CVD (PECVD), and metal-organic CVD (MOCVD) processes. These CVD and PVD devices are equipped with a support device or susceptor to support the glass substrate, flexible substrate, or semiconductor wafer and perform the semiconductor processes. The susceptor may employ a heating wire for heating the substrate during heat treatment processes, employ a high-frequency (RF) electrode, instead of the heating wire, for plasma formation during etching processes of thin film layers formed on the substrate, or employ both the heating wire and the high-frequency (RF) electrode.

In particular, a typical susceptor includes a heating element for heater function, positioned between ceramic materials. In a ceramic susceptor structure, the heating element receives power and generates heat to heat semiconductor wafer substrates or the like, and temperature uniformity across the substrate is important for stable semiconductor processing and yield improvement.

FIG. 1 is a plan view illustrating an example of a heating element pattern of a conventional ceramic susceptor.

Referring to FIG. 1, a conventional ceramic susceptor includes a heating element pattern 21 connected between a pair of terminals 11a and 11b and a heating element pattern 22 connected between a pair of terminals 12a and 12b on the same plane. This shows that the heating element patterns 21 and 22 are configured to form two distinct heating zones.

However, conventional ceramic susceptors have structural problems, such as the wide line width of the heating element patterns 21 and 22 shown in FIG. 1 and the low heating element density, resulting in an uneven temperature distribution across the entire heater area. Furthermore, there are limitations in adjusting the spacing between the heating element patterns 21 and 22 to ensure a uniform temperature across the entire area of the upper surface of the susceptor where the substrate is placed, thereby inevitably resulting in generation of an uneven heating region 26.

Furthermore, due to the symmetrical folded portions of the heating element pattern 21 and 22 such as in FIG. 1, a non-heating region 27 exists in the space between them, and even if a straight connection line portion 25 connecting the terminal pair 12A and 12B and the resistor of the heating element pattern 22 exists in the space between the symmetrical folded portions of the non-heating region 27, the straight connection line portion 25 generates no or little heat, so likewise, there is a problem of causing a cool zone on the upper surface of the susceptor where the substrate is placed and preventing a uniform temperature from being maintained over the entire area of the upper surface. To improve this, a two-layer structure is being attempted, but there is a problem of a hot zone occurring in the section where a main heating element and an auxiliary heating element of the layers overlap.

### SUMMARY OF THE INVENTION

Accordingly, the present disclosure has been made to solve the above-described problems and aims to provide a susceptor in which a coil-type resistor as a main heating element and a 2D wire-type resistor as an auxiliary heating element are configured in a stacked structure to reduce the heat transfer distance and increase the amount of heat transfer to the upper surface, and the main heating element and the auxiliary heating element of each stacked layer are densely interspersed without overlapping each other, thereby improving temperature uniformity over the entire area of the upper surface of the susceptor.

First, to summarize the features of the present disclosure, a susceptor according to one aspect of the present disclosure may include an insulating plate including a main heating element of a first layer and an auxiliary heating element of a second layer, which are stacked, wherein the main heating element is formed as a coil-type resistor connected between respective first terminal pairs and includes first arc portions at different radial positions and first folded portions connected between the first arc portions, wherein the auxiliary heating element is formed as a 2D wire-type resistor connected between respective second terminal pairs and includes second arc portions at different radial positions and second folded portions connected between the second arc portions, and wherein the main heating element and the auxiliary heating element are arranged without overlapping each other between layers across the insulating plate.

The main heating element is disposed above or below the auxiliary heating element.

The main heating element includes a first pattern connected to one of the first terminal pairs to form a single main heating zone across the insulating plate, and the auxiliary heating element includes a second pattern connected to one of the second terminal pairs to form a single compensation heating zone across the insulating plate.

The first pattern includes three, four, or six first repetitive patterns arranged continuously along a circumference, and the second pattern includes a second repetitive pattern corresponding to the first repetitive pattern, the second repetitive pattern being continuous.

The main heating element includes respective first patterns connected to a plurality of the first terminal pairs, the plurality of first patterns forming a plurality of main heating zones dividing the insulating plate, and the auxiliary heating element includes a second pattern connected to one of the second terminal pairs to form a single compensation heating zone across the insulating plate.

The first pattern includes three, four, or six first repetitive patterns arranged separately along a circumference, and the second pattern includes a second repetitive pattern corresponding to the first repetitive pattern, the second repetitive pattern being continuous.

A pattern in which an outermost arc portion of the first pattern is disposed further inward than an outermost arc portion of the second pattern is included.

A pattern in which an outermost arc portion of the first pattern is disposed further outward than an outermost arc portion of the second pattern is included.

The main heating element includes respective first patterns connected to the plurality of first terminal pairs and forming a plurality of main heating zones dividing the insulating plate, and the auxiliary heating element includes respective second patterns connected to the plurality of second terminal pairs and forming a plurality of compensation heating zones dividing the insulating plate.

The main heating element includes three first repetitive patterns for three of the plurality of main heating zones, the three first repetitive patterns being arranged separately along a circumference, and the auxiliary heating element includes a second repetitive pattern for the plurality of compensation heating zones, the second repetitive pattern corresponding to the first repetitive pattern.

The main heating element includes four first repetitive patterns for four of the plurality of main heating zones, the four first repetitive patterns being arranged separately along a circumference, and the auxiliary heating element includes a second repetitive pattern for the plurality of compensation heating zones, the second repetitive pattern corresponding to the first repetitive pattern.

The main heating element includes six first repetitive patterns for six of the plurality of main heating zones, the six first repetitive patterns being arranged separately along a circumference, and the auxiliary heating element includes a second repetitive pattern for the plurality of compensation heating zones, the second repetitive pattern corresponding to the first repetitive pattern.

According to the susceptor of the present disclosure, it is possible to increase the amount of heat transfer to the upper surface by configuring a coil-type resistor as a main heating element and a 2D wire-type resistor as an auxiliary heating element in a stacked structure to reduce the heat transfer distance, and to improve temperature uniformity across the entire area of the upper surface of the susceptor by densely interspersing the main heating element and the auxiliary heating element in respective stacked layers in an empty space without overlapping each other.

Furthermore, according to the susceptor of the present disclosure, compared to the conventional heating elements that have limited spacing control, even when the heating elements are freely arranged, no cool zone occurs in the empty space between the heating elements, thereby ensuring a uniform temperature distribution across the upper surface of the susceptor. Furthermore, since the radially straight connection lines of the conventional heating element pattern are eliminated, and there is no overlap between the main and auxiliary heating element layers, the hot zone may not be formed.

In addition, according to the susceptor of the present disclosure, the auxiliary heating element in the form of a 2D wire has a thin and fine line width and is easy to deform, so it has a high degree of wiring freedom and may be appropriately applied to areas requiring temperature compensation. Furthermore, when the auxiliary heating element is selected in a form that goes around the outer side of the main heating element, it may also be easy to compensate for the temperature of the edge portion, which is a relatively low-heat area.

### BRIEF DESCRIPTION OF THE DRAWINGS

The accompanying drawings, which are included as part of the detailed description to provide a further understanding of the present disclosure, provide embodiments of the present disclosure and, together with the detailed description, serve to explain the technical concept of the present disclosure.

FIG. 1 is a plan view illustrating an example of a heating element pattern in a conventional ceramic susceptor.

FIG. 2 is a schematic cross-sectional view of a susceptor according to an embodiment of the present disclosure.

FIG. 3A is a drawing illustrating the concept of the heating element arrangement applied to a susceptor of the present disclosure.

FIG. 3B is a drawing illustrating heat transfer in a heating element arrangement applied to a conventional technique.

FIG. 4A is a plan view of embodiments of a one-zone main heating element applied to a susceptor of the present disclosure.

FIG. 4B is a plan view of embodiments of a multi-zone main heating element applied to a susceptor of the present disclosure.

FIG. 5A is a plan view of embodiments of a one-zone auxiliary heating element applied to a susceptor of the present disclosure.

FIG. 5B is a plan view of embodiments of another one-zone auxiliary heating element applied to a susceptor of the present disclosure.

FIG. 6A is a plan view of embodiments of a multi-zone auxiliary heating element applied to susceptor of the present disclosure.

FIG. 6B is a plan view of embodiments of another multi-zone auxiliary heating element applied to susceptor of the present disclosure.

FIG. 6C is a plan view of embodiments of another multi-zone auxiliary heating element applied to a susceptor of the present disclosure.

FIG. 6D is a plan view of embodiments of another multi-zone auxiliary heating element applied to a susceptor of the present disclosure.

FIGS. 7A-7C are plan views of embodiments combining the one-zone main heating element in FIG. 4A and the one-zone auxiliary heating element in FIG. 5A.

FIGS. 8A-8C are plan views of embodiments combining the multi-zone main heating element in FIG. 4B and the one-zone auxiliary heating element in FIG. 5A.

FIGS. 9A-9C are plan views of embodiments combining the multi-zone main heating element in FIG. 4B and the one-zone auxiliary heating element in FIG. 5B.

FIGS. 10A-10C are plan views of embodiments combining the multi-zone main heating element in FIG. 4B and the multi-zone auxiliary heating element in FIG. 6A.

FIGS. 11A-11C are plan views of embodiments combining the multi-zone main heating element in FIG. 4B and the multi-zone auxiliary heating element in FIG. 6B.

FIGS. 12A-12C are plan views of embodiments combining the multi-zone main heating element in FIG. 4B and the multi-zone auxiliary heating element in FIG. 6C.

FIGS. 13A-13C are plan views of embodiments combining the multi-zone main heating element in FIG. 4B and the multi-zone auxiliary heating element in FIG. 6D.

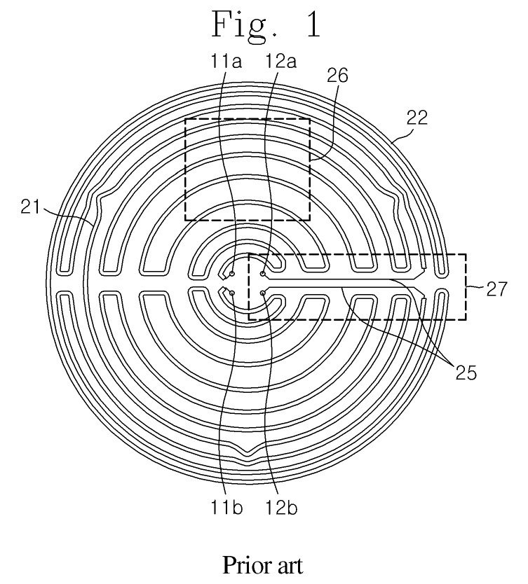

### DETAILED DESCRIPTION OF THE EXEMPLARY EMBODIMENTS

The present disclosure will be described in detail below with reference to the attached drawings. Here, the same components will be assigned the same reference numerals wherever possible. Furthermore, detailed descriptions of previously known functions and/or configurations will be omitted. The following disclosure will focus on the configurations necessary to understand the operation of various embodiments, and descriptions of elements that may obscure the gist of the disclosure will be omitted. Furthermore, some components in the drawings may be exaggerated, omitted, or schematically illustrated. The size of each component does not entirely reflect its actual size, and therefore, the descriptions herein are not limited to the relative sizes or spacing of components depicted in each drawing.

In describing the embodiments of the present disclosure, detailed descriptions of known technologies related to the present disclosure will be omitted if they are deemed to unnecessarily obscure the gist of the present disclosure. In addition, the terms described below are defined in consideration of their functions in the present disclosure, and may vary depending on the intention of a user or an operator, or customs. Therefore, their definitions should be made based on the description throughout this specification. The terms used in the detailed description are merely for describing embodiments of the present disclosure and is not intended to limit the present disclosure. Unless expressly stated otherwise, singular expressions include plural expressions. In the present description, terms such as "comprise" or "include" are intended to indicate certain features, numbers, steps, operations, elements, or portions or combinations thereof, and should not be construed to exclude the presence or possibility of one or more other features, numbers, steps, operations, elements, or portions or combinations thereof other than those described.

Furthermore, terms such as "first," "second," etc. may be used to describe various components, but these components are not limited by these terms, and these terms are used solely to distinguish one component from another.

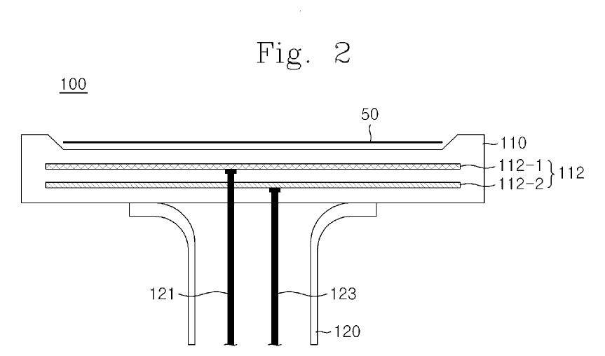

FIG. 2 is a schematic cross-sectional view of a susceptor 100 according to an embodiment of the present disclosure.

Referring to FIG. 2, a susceptor 100 according to an embodiment of the present disclosure includes an insulating plate 110 and a shaft 120.

The susceptor 100 according to an embodiment of the present disclosure is a semiconductor device that supports substrates to be processed for various purposes, such as semiconductor wafers, glass substrates, and flexible substrates, and heats the substrates to be processed to a predetermined temperature. The susceptor 100 may also be used in semiconductor processes that utilize plasma, such as plasma-enhanced chemical vapor deposition or dry etching.

For example, the insulating plate 110 includes an embedded heating element 112. The susceptor of the present disclosure may have a heater function of heating, using the heating element 112, the substrate 50 to be processed to a predetermined temperature during a semiconductor process. In addition, although not illustrated, the susceptor of the present disclosure may include a high-frequency electrode (not shown), and the high-frequency electrode may be used as a plasma electrode for plasma generation in processes such as plasma-enhanced chemical vapor deposition or dry etching in RIE (Reactive Ion Etch) equipment. In some cases, the high-frequency electrode may also be used as a chuck electrode for an electrostatic chuck function to support a substrate 50 placed on the insulating plate 110. In addition, a chuck electrode (not shown) for an electrostatic chuck function may be further provided separately from the high-frequency electrode. In this case, the chuck electrode (not shown) may be disposed at an appropriate location, such as above the high-frequency electrode, between the high-frequency electrode and the heating element 112, or below the heating element 112, so as to be spaced apart from other electrodes.

The shaft 120 is a pipe-shaped structure having a through-hole (hollow interior) and is bonded or coupled to the lower surface of the insulating plate 110. The heating element 112 (112-1 and 112-2) may be connected to power supply rods 121 and 123, respectively, accommodated in the internal space of the hollow shaft 120 through connection with terminals (pairs) on the insulating plate 110, and may receive the required power from the outside through the power supply rods. Here, although only two power supply rods 121 and 123 are illustrated for convenience, more rods may be provided and connected to the terminals on the insulating plate 110. In addition, although power supply rods for electrodes such as the high-frequency electrode (not shown) and the chuck electrode (not shown) are omitted from the drawing, each separate electrode may receive the required power from the outside through another power supply rod accommodated in the internal space of the hollow shaft 120. The insulating plate 110 may be configured to stably support the substrate 50 to be processed, while enabling various semiconductor processes through heating using the heating element 112 and/or plasma generation or electrostatic chucking function using the high-frequency electrode (not shown) or chuck electrode (not shown).

The insulating plate 110 may be formed in a circular plate-like structure made of a ceramic material. However, it is not necessarily limited to the circular shape and may be formed into various shapes as needed. Here, the ceramic material may be at least one of Al₂O₃, Y₂O₃, Al₂O₃/Y₂O₃, ZrO₂, AlC (autoclaved lightweight concrete), TiN, AlN, TiC, MgO, CaO, CeO₂, TiO₂, BₓC_{y}, BN, SiO₂, SiC, YAG, Mullite, and AlF₃, preferably aluminum nitride (AlN). Furthermore, the ceramic material powder may be molded and sintered to form the insulating plate 110, and each ceramic powder for this purpose may optionally include about yttrium oxide powder of about 0.1 to 10%, preferably about 1 to 5%.

The shaft 120 may be formed of the same ceramic material as the insulating plate 110 and may be bonded or coupled to the insulating plate 110. Here, the ceramic material may also be at least one of Al₂O₃, Y₂O₃, Al₂O₃/Y₂O₃, ZrO₂, AlC (Autoclaved lightweight concrete), TiN, AlN, TiC, MgO, CaO, CeO₂, TiO₂, BₓC_{y}, BN, SiO₂, SiC, YAG, Mullite, and AlF₃, preferably aluminum nitride (AlN). Furthermore, the above ceramic material powder may be molded and sintered to form the shaft 130 and each ceramic powder for this purpose may optionally include yttrium oxide powder of about 0.1 to 10%, preferably about 1 to 5%.

The high-frequency electrode (not shown) or chuck electrode (not shown) may be made of tungsten (W), molybdenum (Mo), silver (Ag), gold (Au), niobium (Nb), titanium (Ti), or an alloy thereof, preferably molybdenum (Mo). The high-frequency electrode has a mesh structure of a wire type or a sheet type. Here, the mesh structure is a net-like structure formed by intersecting multiple metals arranged in a first direction and multiple metals arranged in a second direction.

The heating element 112 is made of tungsten (W), molybdenum (Mo), an alloy thereof, or a carbide, and has a high melting point and high resistance. The heating element 112 may be formed as a coil-type resistor using a heating wire (or resistance wire or heating electrode), a 2D wire-type resistor, or a sheet-type resistor. The heating element 112 may be configured in a multi-layer structure of two or more layers for precise temperature control.

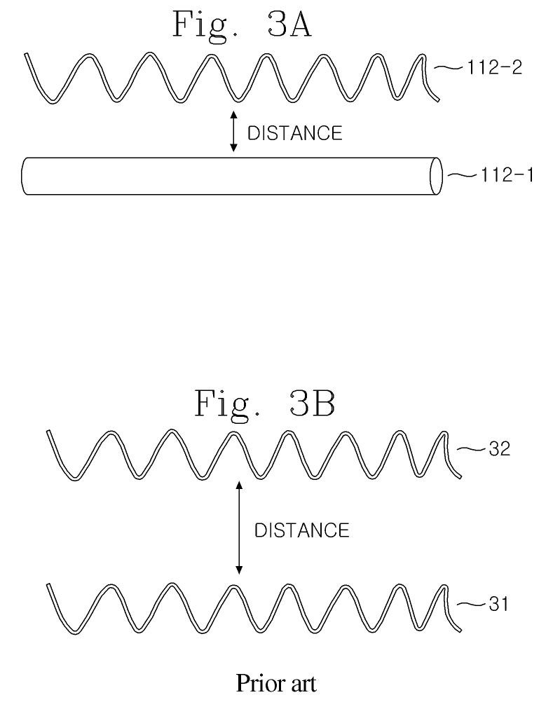

FIG. 3A is a drawing illustrating the concept of arrangement of a heating element 112 applied to a susceptor 100 of the present disclosure.

Referring to FIG. 3A, the susceptor 100 of the present disclosure may include a main heating element 112-2 in the first layer and an auxiliary heating element 112-1 in the second layer. Although the following description exemplifies the main heating element 112-2 disposed in the upper layer and the auxiliary heating element 112-1 disposed in the lower layer, the present disclosure is not limited thereto, and the main heating element 112-2 may be disposed in the lower layer and the auxiliary heating element 112-1 may be disposed in the upper layer.

In particular, in an embodiment of the present disclosure, the main heating element 112-2 may be formed as a coil-type resistor, and the auxiliary heating element 112-1 may be formed as a 2D wire-type resistor.

The coil-type resistor refers to a resistor wire made of the material described above and wound and disposed in a coil shape. As shown in FIG. 3A, the main heating element 112-2 embedded in the insulating plate 110 has a height difference between the upper surface and the lower surface of the insulating plate 110. The 2D wire-type resistor refers to a resistor wire made of the material described above and disposed in a straight line, curve, or other shape on a two-dimensional plane. As shown in FIG. 3A, the auxiliary heating element 112-1 embedded in the insulating plate 110 is disposed without a height difference between the upper surface and the lower surface of the insulating plate 110. The 2D wire-type resistor provides design flexibility compared to the coil-type resistor, thereby allowing various arrangements.

Accordingly, the auxiliary heating element 112-1 of the present disclosure may transfer more heat to the upper surface of the insulating plate 110 within the same period of time, thereby increasing heat generation. This is due to the fact that the auxiliary heating element 112-1 may achieve a relatively short heat transfer distance when positioned with a minimal distance from the main heating element 112-2.

FIG. 3B is a drawing illustrating heat transfer in a heating element arrangement applied to a conventional technique.

As shown in FIG. 3B, in the prior art, when heating elements 31 and 32 configured as coil-type resistors are stacked in a two-layer structure, the lower heating element 31 has a height difference relative to the upper surface of the insulating plate 110, resulting in a relatively greater heat transfer distance to the upper surface of the insulating plate 110 than the auxiliary heating element 112-1 of the present disclosure. This is due to the fact that the distance between the upper heating element 32 and the lower heating element 31 is the distance between coils with varying heights, while the distance between the main heating element 112-2 and the auxiliary heating element 112-1 of the present disclosure is the distance between the coil of the main heating element 112-2 and the fixed height of the auxiliary heating element 112-1.

The present disclosure has advantages of shortening the heat transfer distance and increasing the amount of heat transfer to the upper surface of the insulating plate 110, and provides the design flexibility of the 2D wire-type resistor of the auxiliary heating element 112-1 of the present disclosure, which enables the main heating element 112-2 and the auxiliary heating element 112-1 in the respective stacked layers to be densely interspersed across the entire insulating plate 110 without overlapping, thereby improving temperature uniformity across the entire area of the upper surface of the susceptor 100.

Furthermore, according to the susceptor 100 of the present disclosure, compared to the conventional heating elements that have limited spacing control, even when the heating elements are freely arranged, no cool zone occurs in the empty space between the heating elements, thereby ensuring a uniform temperature distribution across the upper surface of the susceptor. Furthermore, since the radially straight connection lines of the conventional heating element pattern are eliminated, and there is no overlap between the main and auxiliary heating element layers, the hot zone may not be formed.

In addition, according to the susceptor 100 of the present disclosure, the auxiliary heating element 112-1 in the form of a 2D wire has a thin and fine line width and is easy to deform, so it has a high degree of wiring freedom and may be appropriately applied to areas requiring temperature compensation. Furthermore, when the auxiliary heating element 112-1 is selected in a form that goes around the outer side of the main heating element 112-2, it may also be easy to compensate for the temperature of the edge portion, which is a relatively low-heat area.

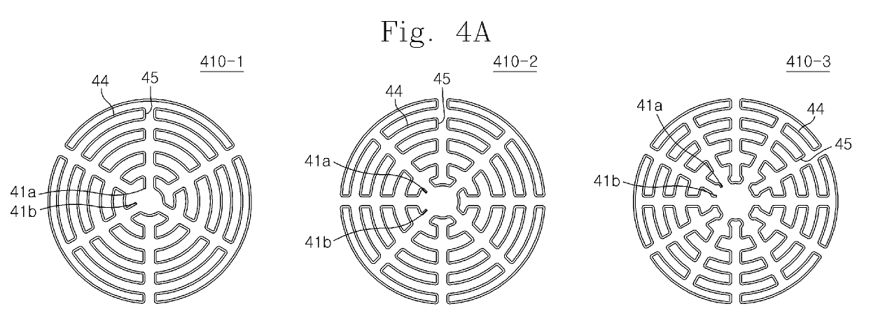

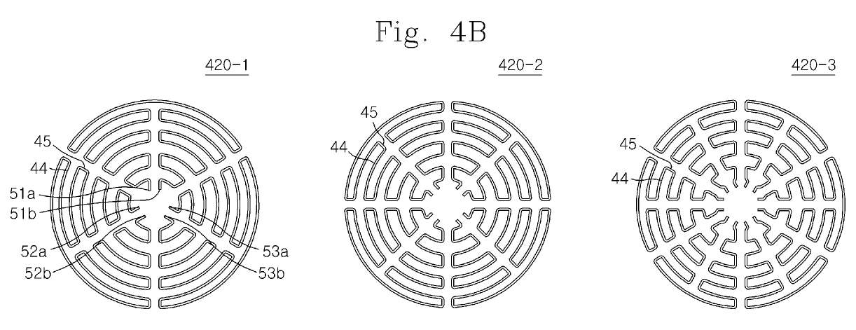

FIG. 4A is a plan view of embodiments 410-1, 410-2, and 410-3 of a one-zone main heating element 112-2 (a main heating element positioned in one zone) applied to a susceptor 100 of the present disclosure.

Referring to FIG. 4A, a first one-zone main heating element 410-1 including three identical repetitive patterns (three sections) continuously arranged along the circumference, a second one-zone main heating element 410-2 including four identical repetitive patterns (four sections) continuously arranged along the circumference, and a third one-zone main heating element 410-3 including six identical repetitive patterns (six sections) continuously arranged along the circumference are illustrated. Each repetitive pattern includes arc portions 44 at different radial positions and folded portions 45 connecting the arc portions 44.

Here, one zone refers to a single heating zone formed by repetitive patterns connected to a single terminal pair at predetermined ends 81a and 81b across the entire insulating plate 110. This refers to three, four, or six (or more) identical repetitive patterns, as described above, arranged in a continuous manner without disconnection. The heating zone corresponds to a main heating zone when using the main heating element 112-2. These terms apply in the same manner hereinafter.

FIG. 4B is a plan view of embodiments 420-1, 420-2, and 420-3 of a multi-zone main heating element 112-2 applied to a susceptor 100 of the present disclosure.

Referring to FIG. 4B, a first multi-zone main heating element 420-1 including three identical repetitive patterns (three sections) separately arranged along the circumference, a second multi-zone main heating element 420-2 including four identical repetitive patterns (four sections) separately arranged along the circumference, and a third multi-zone main heating element 420-3 including six identical repetitive patterns (six sections) separately arranged along the circumference are illustrated. Each repetitive pattern includes arc portions 44 at different radial positions and folded portions 45 connecting the arc portions 44.

Here, multi-zone refers to a plurality of heating zones formed by dividing the insulating plate 110 according to the respective repetitive patterns that are connected to a plurality of terminal pairs at their ends 51a and 51b, 52a and 52b, and 53a and 53b, respectively. It indicates arrangement of three, four, or six (or more) identical repetitive patterns, as described above, which are disconnected and separate. Although the ends of the second multi-zone main heating element 420-2 and the third multi-zone main heating element 420-3 connected to the terminal pairs are not assigned reference numerals in the drawing, it may be understood from the drawings that there may be four and six terminal pairs, respectively.

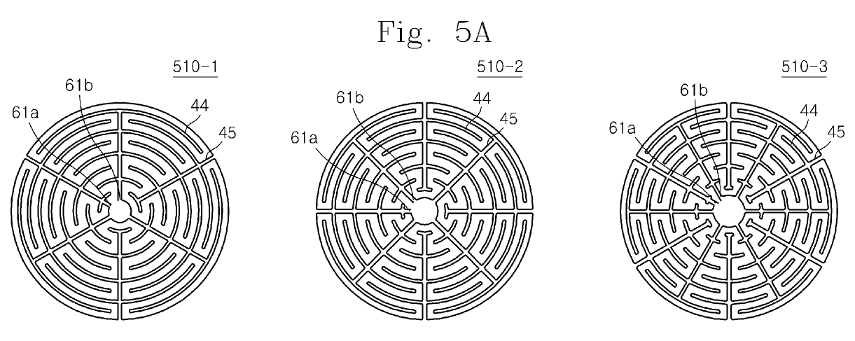

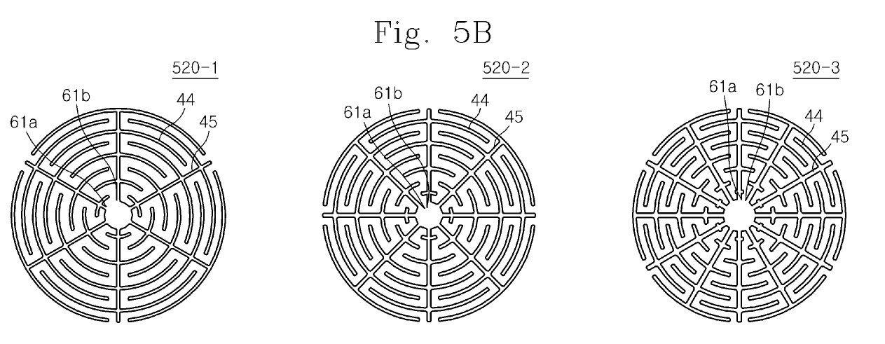

FIG. 5A is a plan view of embodiments 510-1, 510-2, and 510-3 of a one-zone auxiliary heating element 112-1 applied to a susceptor 100 of the present disclosure.

FIG. 5B is a plan view of embodiments 520-1, 520-2, and 520-3 of another one-zone auxiliary heating element 112-1 applied to a susceptor 100 of the present disclosure.

Referring to FIG. 5A, a first one-zone auxiliary heating element 510-1 including three identical repetitive patterns (three sections) continuously arranged along the circumference, a second one-zone auxiliary heating element 510-2 including four identical repetitive patterns (four sections) continuously arranged along the circumference, and a third one-zone auxiliary heating element 510-3 including six identical repetitive patterns (six sections) continuously arranged along the circumference are illustrated.

Referring to FIG. 5B, a fourth one-zone auxiliary heating element 520-1 including three identical repetitive patterns (three sections) continuously arranged along the circumference, a fifth one-zone auxiliary heating element 520-2 including four identical repetitive patterns (four sections) continuously arranged along the circumference, and a sixth one-zone auxiliary heating element 520-3 including six identical repetitive patterns (six sections) continuously arranged along the circumference are illustrated.

In FIGS. 5A and 5B, each repetitive pattern includes arc portions 44 at different radial positions and folded portions 45 connecting the arc portions 44. Here, the repetitive patterns for one zone are connected to a single terminal pair at predetermined ends 61a and 61b to form a single heating zone, i.e., a compensation heating zone, throughout the insulating plate 110.

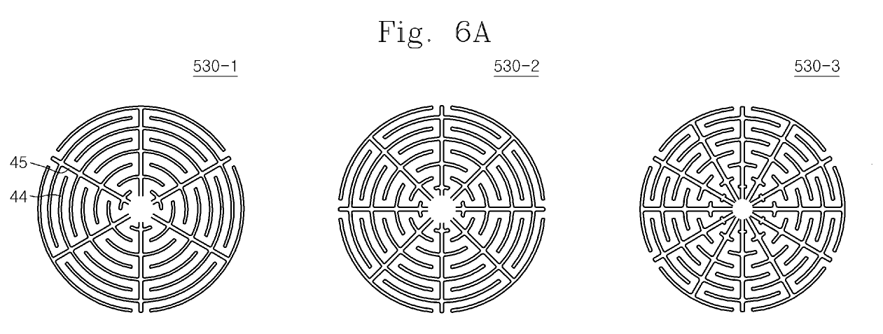

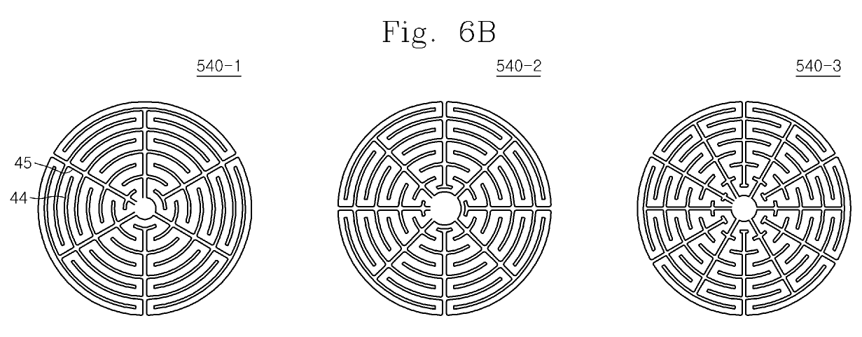

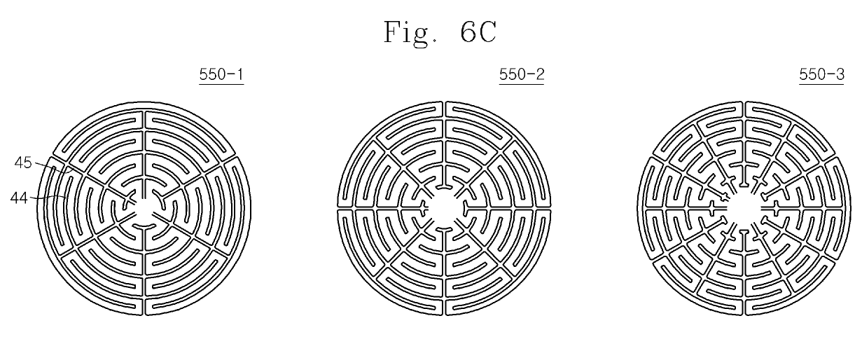

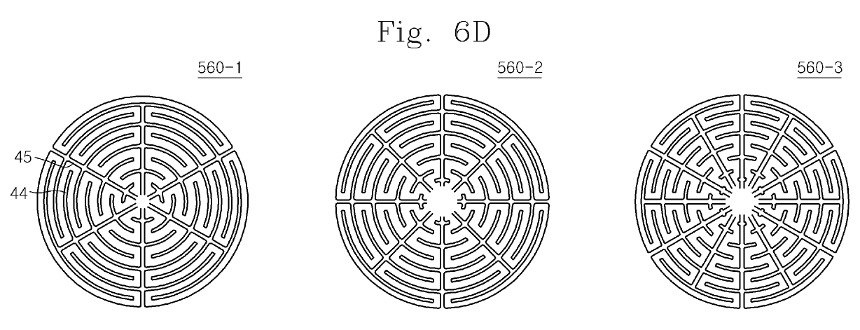

FIG. 6A is a plan view of embodiments of a multi-zone auxiliary heating element 112-1 applied to susceptor 100 of the present disclosure.

FIG. 6B is a plan view of embodiments of another multi-zone auxiliary heating element 112-1 applied to susceptor 100 of the present disclosure.

FIG. 6C is a plan view of embodiments of another multi-zone auxiliary heating element 112-1 applied to a susceptor 100 of the present disclosure.

FIG. 6D is a plan view of embodiments of another multi-zone auxiliary heating element 112-1 applied to a susceptor 100 of the present disclosure.

Referring to FIG. 6A, a first multi-zone auxiliary heating element 530-1 including three identical repetitive patterns (three sections) separately arranged along the circumference, a second multi-zone auxiliary heating element 530-2 including four identical repetitive patterns (four sections) separately arranged along the circumference, and a third multi-zone auxiliary heating element 530-3 including six identical repetitive patterns (six sections) separately arranged along the circumference are illustrated. Each repetitive pattern includes arc portions 44 at different radial positions and folded portions 45 connecting the arc portions 44. Here, the repetitive patterns for the multi-zone are connected to the plurality of terminal pairs, respectively, at their predetermined ends, so that the respective repetitive patterns form heating zones dividing the insulating plate 110, thereby providing a plurality of heating zones, i.e., a plurality of compensation heating zones.

Although the ends of the first multi-zone auxiliary heating element 530-1, the second multi-zone auxiliary heating element 530-2, and the third multi-zone auxiliary heating element 530-3 connected to the plurality of terminal pairs are not assigned reference numerals in the drawing, the unconnected ends of the central pattern correspond to the portions connected to the respective terminal pairs. In FIG. 6A, the terminal pairs of the first multi-zone auxiliary heating element 530-1, the second multi-zone auxiliary heating element 530-2, and the third multi-zone auxiliary heating element 530-3 are 6, 8, and 12, respectively.

Referring to FIG. 6B, a fourth multi-zone auxiliary heating element 540-1 including three identical repetitive patterns (three sections) separately arranged along the circumference, a fifth multi-zone auxiliary heating element 540-2 including four identical repetitive patterns (four sections) separately arranged along the circumference, and a sixth multi-zone auxiliary heating element 540-3 including six identical repetitive patterns (six sections) separately arranged along the circumference are illustrated. Each repetitive pattern includes arc portions 44 at different radial positions and folded portions 45 connecting the arc portions 44. Here, the repetitive patterns for the multi-zone are connected to a plurality of terminal pairs, respectively, at their predetermined ends, so that the respective repetitive patterns form heating zones dividing the insulating plate 110, thereby providing a plurality of heating zones, i.e., a plurality of compensation heating zones.

Although the ends of the fourth multi-zone auxiliary heating element 540-1, the fifth multi-zone auxiliary heating element 540-2, and the sixth multi-zone auxiliary heating element 540-3 connected to the plurality of terminal pairs are not assigned reference numerals in the drawing, the unconnected ends of the central pattern correspond to the portions connected to the respective terminal pairs. In FIG. 6B, the terminal pairs of the fourth multi-zone auxiliary heating element 540-1, the fifth multi-zone auxiliary heating element 540-2, and the sixth multi-zone auxiliary heating element 540-3 are 2, 2, and 2, respectively.

Referring to FIG. 6C, a seventh multi-zone auxiliary heating element 550-1 including three identical repetitive patterns (three sections) separately arranged along the circumference, an eighth multi-zone auxiliary heating element 550-2 including four identical repetitive patterns (four sections) separately arranged along the circumference, and a ninth multi-zone auxiliary heating element 550-3 including six identical repetitive patterns (six sections) separately arranged along the circumference are illustrated. Each repetitive pattern includes an arc portion 44 at a different radial position and folded portions 45 connecting the arc portions 44. Here, the repetitive patterns for the multi-zone are connected to a plurality of terminal pairs, respectively, at their predetermined ends, so that the respective repetitive patterns form heating zones dividing the insulating plate 110, thereby providing a plurality of heating zones, i.e., a plurality of compensation heating zones.

Although the ends of the seventh multi-zone auxiliary heating element 550-1, the eighth multi-zone auxiliary heating element 550-2, and the ninth multi-zone auxiliary heating element 550-3 connected to the plurality of terminal pairs are not assigned reference numerals in the drawing, the unconnected ends of the central pattern correspond to the portions connected to the respective terminal pairs. In FIG. 6C, the terminal pairs of the seventh multi-zone auxiliary heating element 550-1, the eighth multi-zone auxiliary heating element 550-2, and the ninth multi-zone auxiliary heating element 550-3 are 4, 5, and 7, respectively.

Referring to FIG. 6D, a tenth multi-zone auxiliary heating element 560-1 including three identical repetitive patterns (three sections) separately arranged along the circumference, an eleventh multi-zone auxiliary heating element 560-2 including four identical repetitive patterns (four sections) separately arranged along the circumference, and a twelfth multi-zone auxiliary heating element 560-3 including six identical repetitive patterns (six sections) separately arranged along the circumference are illustrated. Each repetitive pattern includes arc portions 44 at different radial positions and folded portions 45 connecting the arc portions 44. Here, the repetitive patterns for the multi-zone are connected to a plurality of terminal pairs, respectively, at their predetermined ends, so that the respective repetitive patterns form heating zones dividing the insulating plate 110, thereby providing a plurality of heating zones, i.e., a plurality of compensation heating zones.

Although the ends of the tenth multi-zone auxiliary heating element 560-1, the eleventh multi-zone auxiliary heating element 560-2, and the twelfth multi-zone auxiliary heating element 560-3 connected to the plurality of terminal pairs are not assigned reference numerals in the drawing, the unconnected ends of the central pattern correspond to the portions connected to the respective terminal pairs. In FIG. 6D, the terminal pairs of the tenth multi-zone auxiliary heating element 560-1, the eleventh multi-zone auxiliary heating element 560-2, and the twelfth multi-zone auxiliary heating element 560-3 are 6, 8, and 12, respectively.

Hereinafter, the structure of arranging a combination of the one-zone/multi-zone main heating element 112-2 in FIGS. 4A and 4B and the one-zone/multi-zone auxiliary heating element 112-1 in FIGS. 5A-5B and FIGS. 6A-6D in respective layers will be described in detail.

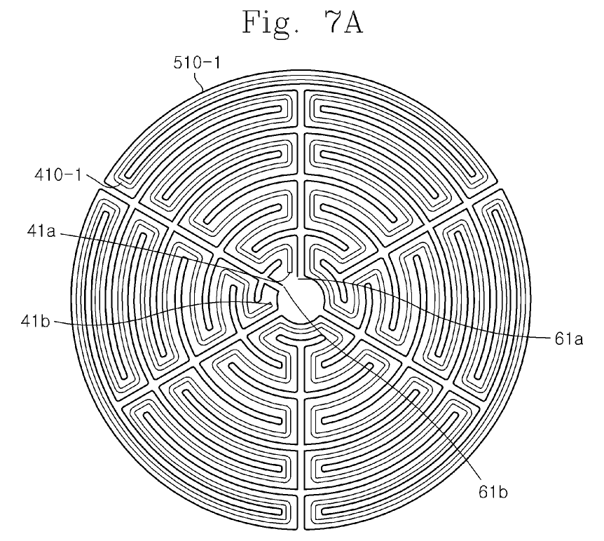

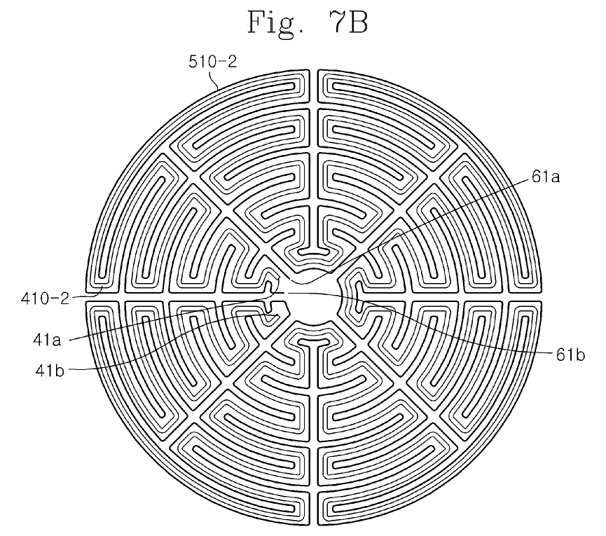

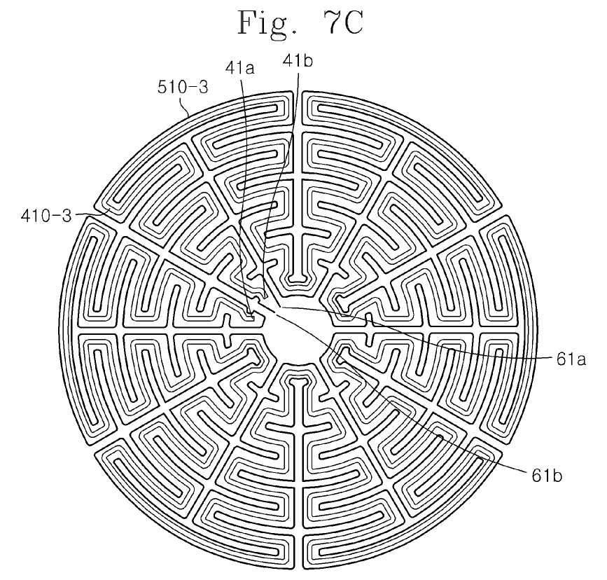

FIGS. 7A-7C are plan views of embodiments combining the one-zone main heating elements 410-1, 410-2, and 410-3 in FIG. 4A and the one-zone auxiliary heating elements 510-1, 510-2, and 510-3 in FIG. 5A. That is, respective embodiments here represent a combination of 410-1 and 510-1 for three sections, a combination of 410-2 and 510-2 for four sections, and a combination of 410-3 and 510-3 for six sections, respectively.

Referring to FIGS. 7A-7C, the one-zone main heating elements 410-1, 410-2, and 410-3 and the one-zone auxiliary heating elements 510-1, 510-2, and 510-3 are disposed without overlapping each other between layers across the entire insulating plate 110.

The one-zone main heating elements 410-1, 410-2, and 410-3 include a pattern in which predetermined ends 41a and 41b are connected to a single terminal pair to form a single main heating zone across the insulating plate 110.

The one-zone auxiliary heating elements 510-1, 510-2, and 510-3 include a pattern in which predetermined ends 61a and 61b are connected to a single terminal pair to form a single compensation heating zone across the insulating plate 110.

In FIG. 7A, the one-zone main heating element 410-1 includes three identical repetitive patterns arranged continuously along the circumference in the three sections. Furthermore, the one-zone auxiliary heating element 510-1 includes patterns corresponding to the three repetitive patterns of the one-zone main heating element 410-1.

In FIG. 7B, the one-zone main heating element 410-2 includes four identical repetitive patterns arranged continuously along the circumference in the four sections. Furthermore, the one-zone auxiliary heating element 510-2 includes patterns corresponding to the four repetitive patterns of the one-zone main heating element 410-2.

In FIG. 7C, the one-zone main heating element 410-3 includes six identical repetitive patterns arranged continuously along the circumference in the six sections. In addition, the one-zone auxiliary heating element 510-3 includes patterns corresponding to the six repetitive patterns of the one-zone main heating element 410-3.

FIGS. 7A-7C show structures in which the outermost arc portion of the pattern of the one-zone auxiliary heating element 510-1, 510-2, or 510-3 is positioned further outward to surround the outermost arc portion of the pattern of the one-zone main heating element 410-1, 410-2, or 410-3. Since there is no vertical overlap between the patterns of the one-zone main heating elements 410-1, 410-2, and 410-3 and the patterns of the one-zone auxiliary heating elements 510-1, 510-2, and 510-3, there is no risk of generating hot zones. The respective patterns of the one-zone main heating elements 410-1, 410-2, and 410-3 and the one-zone auxiliary heating elements 510-1, 510-2, and 510-3 do not have non-heating straight sections, unlike conventional heating elements. Furthermore, the pattern of the one-zone auxiliary heating element 510-1, 510-2, or 510-3 is a 2D wire-type resistor, which allows free and flexible arrangement without overlapping with the pattern of the one-zone main heating element 410-1, 410-2, or 410-3, which is a coil-type resistor.

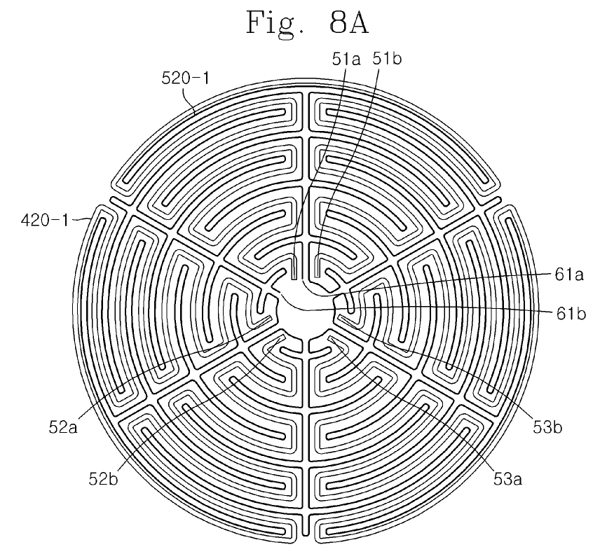

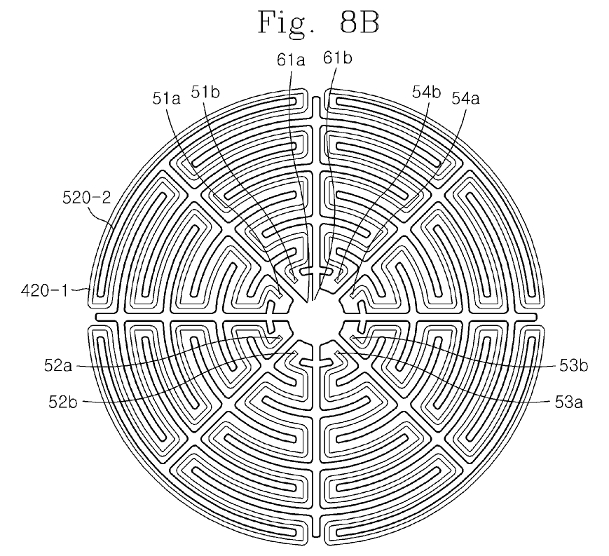

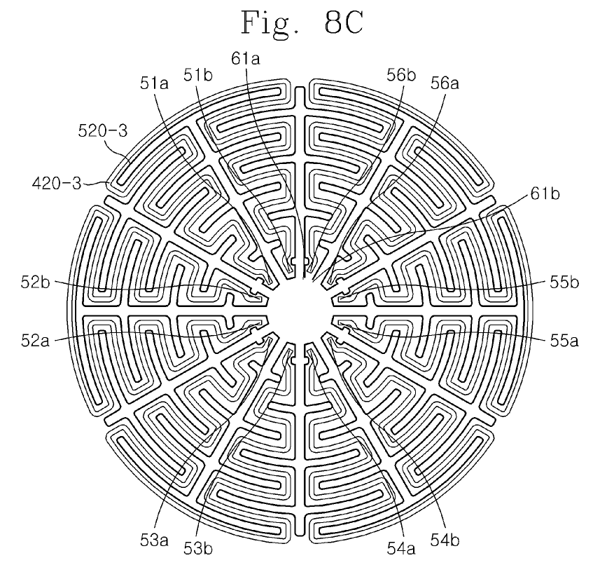

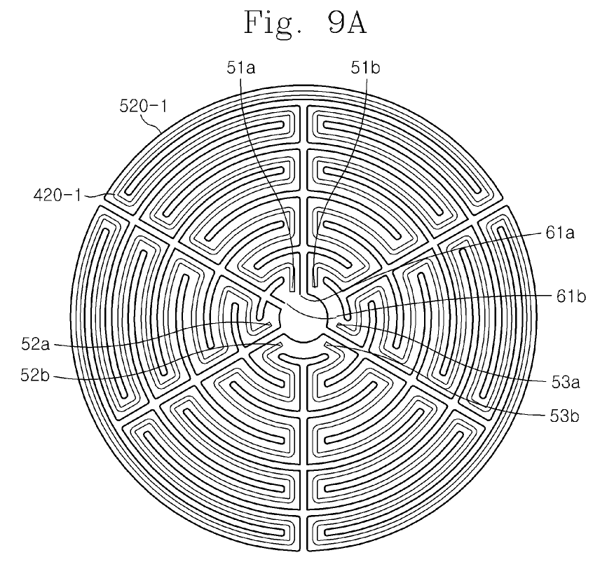

FIGS. 8A-8C are plan views of embodiments combining the multi-zone main heating elements 420-1, 420-2, and 420-3 in FIG. 4B and the one-zone auxiliary heating elements 520-1, 520-2, and 520-3 in FIG. 5B. That is, respective embodiments here represent a combination of 420-1 and 520-1 for three sections, a combination of 420-2 and 520-2 for four sections, and a combination of 420-3 and 520-3 for six sections, respectively.

Referring to FIGS. 8A-8C, the multi-zone main heating elements 420-1, 420-2, and 420-3 and the one-zone auxiliary heating elements 520-1, 520-2, and 520-3 are disposed without overlapping each other between layers across the entire insulating plate 110.

The multi-zone main heating element 420-1 includes a pattern in which predetermined ends 51a and 51b, 52a and 52b, and 53a and 53b are connected to different terminal pairs, respectively, to form a plurality of heating zones dividing the insulating plate 110. The multi-zone main heating element 420-2 includes predetermined ends 51a and 51b, 52a and 52b, and 53a and 53b connected to different terminal pairs, respectively. The multi-zone main heating element 420-3 includes predetermined ends 51a and 51b, 52a and 52b, 53a and 53b, 54a and 54b, 55a and 55b, and 56a and 56b connected to different terminal pairs, respectively.

The one-zone auxiliary heating elements 520-1, 520-2, and 520-3 include a pattern in which predetermined ends 61a and 61b are connected to a single terminal pair to form a single compensation heating zone across the entire insulating plate 110.

In FIG. 8A, the multi-zone main heating element 420-1 includes three identical repetitive patterns arranged separately along the circumference in the three sections. Furthermore, the one-zone auxiliary heating element 520-1 includes patterns corresponding to the three repetitive patterns of the multi-zone main heating element 420-1.

In FIG. 8B, the multi-zone main heating element 420-2 includes four identical repetitive patterns arranged separately along the circumference in the four sections. Furthermore, the one-zone auxiliary heating element 520-2 includes patterns corresponding to the four repetitive patterns of the multi-zone main heating element 420-2.

In FIG. 8C, the multi-zone main heating element 420-3 includes six identical repetitive patterns arranged separately along the circumference in the six sections. In addition, the one-zone auxiliary heating element 520-3 includes patterns corresponding to the six repetitive patterns of the multi-zone main heating element 420-3.

FIGS. 8A, 8B, and 8C show structures in which the outermost arc portion of the pattern of the multi-zone main heating element 420-1, 420-2, or 420-3 is positioned further outward to surround the outermost arc portion of the pattern of the one-zone auxiliary heating element 520-1, 520-2, or 520-3. Since there is no vertical overlap between the patterns of the multi-zone main heating elements 420-1, 420-2, and 420-3 and the patterns of the one-zone auxiliary heating elements 520-1, 520-2, and 520-3, there is no risk of generating hot zones. The respective patterns of the multi-zone main heating elements 420-1, 420-2, and 420-3 and the one-zone auxiliary heating elements 520-1, 520-2, and 520-3 do not have non-heating straight sections, unlike conventional heating elements. Furthermore, the pattern of the one-zone auxiliary heating element 520-1, 520-2, and 520-3 is a 2D wire-type resistor, which allows free and flexible arrangement without overlapping with the pattern of the one-zone main heating element 420-1, 420-2, or 420-3, which is a coil-type resistor.

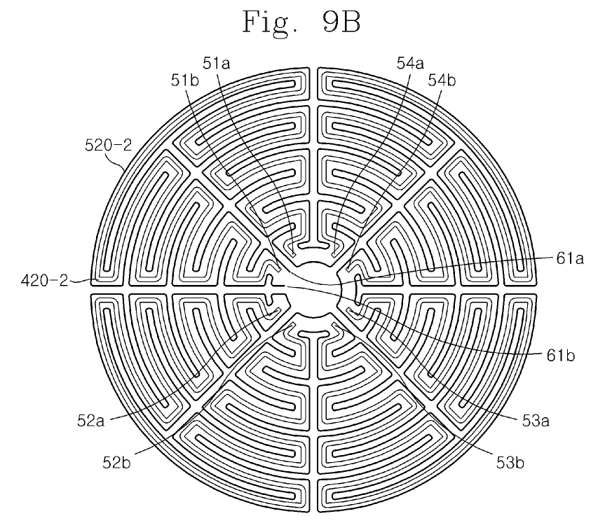

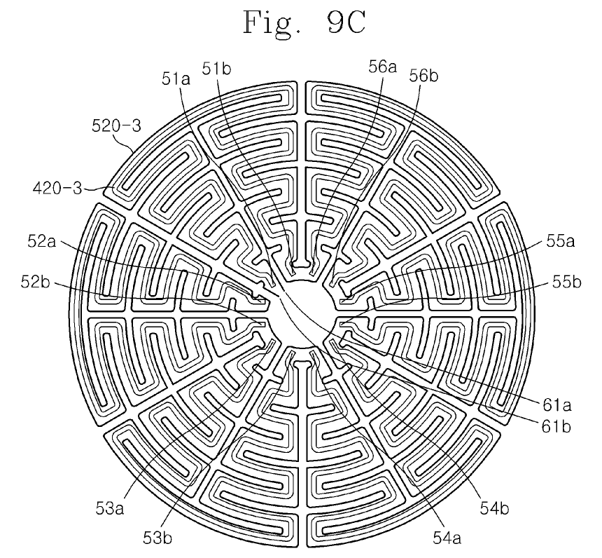

FIGS. 9A-9C are plan views of embodiments combining the multi-zone main heating elements 420-1, 420-2, and 420-3 in FIG. 4B and the one-zone auxiliary heating elements 520-1, 520-2, and 520-3 in FIG. 5B. That is, respective embodiments here represent a combination of 420-1 and 520-1 for three sections, a combination of 420-2 and 520-2 for four sections, and a combination of 420-3 and 520-3 for six sections, respectively.

Referring to FIGS. 9A-9C, the multi-zone main heating elements 420-1, 420-2, and 420-3 and the one-zone auxiliary heating elements 520-1, 520-2, and 520-3 are disposed without overlapping each other between layers across the entire insulating plate 110.

The multi-zone main heating element 420-1 includes a pattern in which predetermined ends 51a and 51b, 52a and 52b, and 53a and 53b are connected to different terminal pairs, respectively, to form a plurality of heating zones dividing the insulating plate 110. The multi-zone main heating element 420-2 includes predetermined ends 51a and 51b, 52a and 52b, 53a and 53b, and 54a and 54b connected to different terminal pairs, respectively. The multi-zone main heating element 420-3 includes predetermined ends 51a and 51b, 52a and 52b, 53a and 53b, 54a and 54b, 55a and 55b, and 56a and 56b connected to different terminal pairs, respectively.

The one-zone auxiliary heating elements 520-1, 520-2, and 520-3 include a pattern in which predetermined ends 61a and 61b are connected to a single terminal pair to form a single compensation heating zone across the entire insulating plate 110.

In FIG. 9A, the multi-zone main heating element 420-1 includes three identical repetitive patterns arranged separately along the circumference in the three sections. In addition, the one-zone auxiliary heating element 510-1 includes patterns corresponding to the three repetitive patterns of the multi-zone main heating element 420-1.

In FIG. 9B, the multi-zone main heating element 420-2 includes four identical repetitive patterns arranged separately along the circumference in the four sections. In addition, the one-zone auxiliary heating element 510-2 includes patterns corresponding to the four repetitive patterns of the multi-zone main heating element 420-2.

In FIG. 9C, the multi-zone main heating element 420-3 includes six identical repetitive patterns arranged separately along the circumference in the six sections. In addition, the one-zone auxiliary heating element 510-3 includes patterns corresponding to the six repetitive patterns of the multi-zone main heating element 420-3.

FIGS. 9A-9C show structures in which the outermost arc portion of the pattern of the one-zone auxiliary heating element 520-1, 520-2, or 520-3 is positioned further outward to surround the patterns of the multi-zone main heating elements 420-1, 420-2, and 420-3. Since there is no vertical overlap between the patterns of the multi-zone main heating elements 420-1, 420-2, and 420-3 and the patterns of the one-zone auxiliary heating elements 520-1, 520-2, and 520-3, there is no risk of generating hot zones. The respective patterns of the multi-zone main heating elements 420-1, 420-2, and 420-3 and the one-zone auxiliary heating elements 520-1, 520-2, and 520-3 do not have non-heating straight sections, unlike conventional heating elements. Furthermore, the pattern of the one-zone auxiliary heating element 520-1, 520-2, or 520-3 is a 2D wire-type resistor, which allows free and flexible arrangement without overlapping with the pattern of the one-zone main heating element 420-1, 420-2, or 420-3, which is a coil-type resistor.

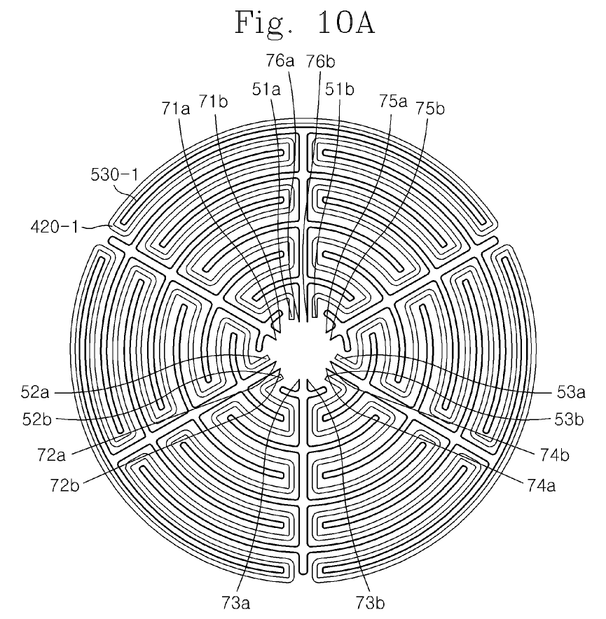

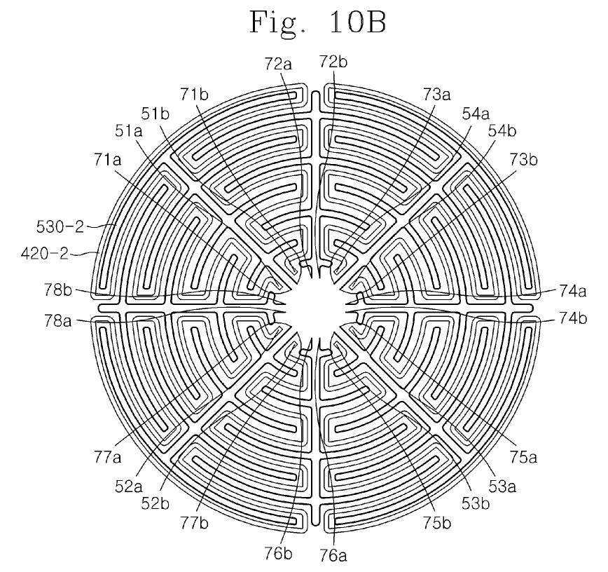

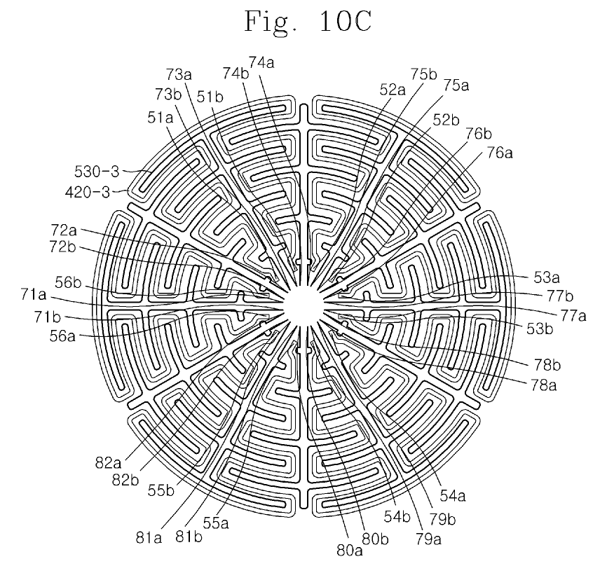

FIGS. 10A-10C are plan views of embodiments combining the multi-zone main heating elements 420-1, 420-2, and 420-3 in FIG. 4B and the multi-zone auxiliary heating elements 530-1, 530-2, and 530-3 in FIG. 6A. That is, respective embodiments here represent a combination of 420-1 and 530-1 for three sections, a combination of 420-2 and 530-2 for four sections, and a combination of 420-3 and 530-3 for six sections, respectively.

Referring to FIGS. 10A-10C, the multi-zone main heating elements 420-1, 420-2, and 420-3 and the one-zone auxiliary heating elements 530-1, 530-2, and 530-3 are disposed without overlapping each other between layers across the entire insulating plate 110.

The multi-zone main heating element 420-1 includes a pattern in which predetermined ends 51a and 51b, 52a and 52b, and 53a and 53b are connected to different terminal pairs, respectively, to form a plurality of heating zones dividing the insulating plate 110. The multi-zone main heating element 420-2 includes predetermined ends 51a and 51b, 52a and 52b, 53a and 53b, and 54a and 54b connected to different terminal pairs, respectively. The multi-zone main heating element 420-3 includes predetermined ends 51a and 51b, 52a and 52b, 53a and 53b, 54a and 54b, 55a and 55b, and 56a and 56b connected to different terminal pairs, respectively.

The multi-zone auxiliary heating element 530-1 includes a pattern in which predetermined ends 71a and 71b, 72a and 72b, 73a and 73b, 74a and 74b, 75a and 75b, and 76a and 76b are connected to different terminal pairs (6 pairs), respectively, to form a plurality of heating zones dividing the insulating plate 110. The multi-zone auxiliary heating element 530-2 includes predetermined ends 71a and 71b, 72a and 72b, 73a and 73b, 74a and 74b, 75a and 75b, 76a and 76b, 77a and 77b, and 78a and 78b connected to different terminal pairs (8 pairs), respectively. The multi-zone auxiliary heating element 530-3 has predetermined terminals 71a and 71b, 72a and 72b, 73a and 73b, 74a and 74b, 75a and 75b, 76a and 76b, 77a and 77b, 78a and 78b, 79a and 79b, 80a and 80b, 81a and 81b, and 82a and 82b connected to different terminal pairs (12 pairs), respectively.

In FIG. 10A, the multi-zone main heating element 420-1 includes three identical repetitive patterns arranged separately along the circumference in the three sections. In addition, the multi-zone auxiliary heating element 530-1 includes patterns corresponding to the three repetitive patterns of the multi-zone main heating element 420-1.

In FIG. 10B, the multi-zone main heating element 420-2 includes four identical repetitive patterns arranged separately along the circumference in the four sections. In addition, the multi-zone auxiliary heating element 530-2 includes patterns corresponding to the four repetitive patterns of the multi-zone main heating element 420-2.

In FIG. 10C, the multi-zone main heating element 420-3 includes six identical repetitive patterns arranged separately along the circumference in the six sections. In addition, the multi-zone auxiliary heating element 530-3 includes patterns corresponding to the six repetitive patterns of the multi-zone main heating element 420-3.

FIGS. 10A-10C show structures in which the outermost arc portion of the pattern of the multi-zone main heating element 420-1, 420-2, or 420-3 is positioned further outward to surround the outermost arc portion of the pattern of the multi-zone auxiliary heating element 530-1, 530-2, or 530-3. Since there is no vertical overlap between the patterns of the multi-zone main heating elements 420-1, 420-2, and 420-3 and the patterns of the multi-zone auxiliary heating elements 530-1, 530-2, and 530-3, there is no risk of generating hot zones. The respective patterns of the multi-zone main heating elements 420-1, 420-2, and 420-3 and the multi-zone auxiliary heating elements 530-1, 530-2, and 530-3 do not have non-heating straight sections, unlike conventional heating elements. Furthermore, the pattern of the multi-zone auxiliary heating element 530-1, 530-2, or 530-3 is a 2D wire-type resistor, which allows free and flexible arrangement without overlapping with the pattern of the multi-zone main heating element 420-1, 420-2, or 420-3, which is a coil-type resistor, thereby compensating for temperature while being disposed between the patterns of the main heating elements 420-1, 420-2, and 420-3.

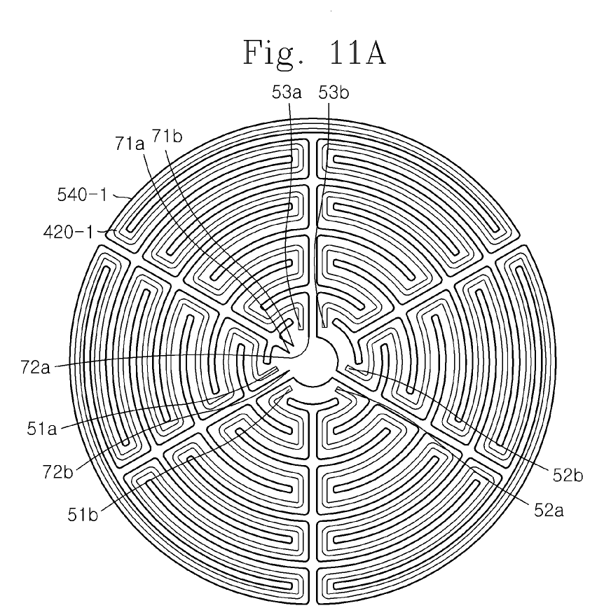

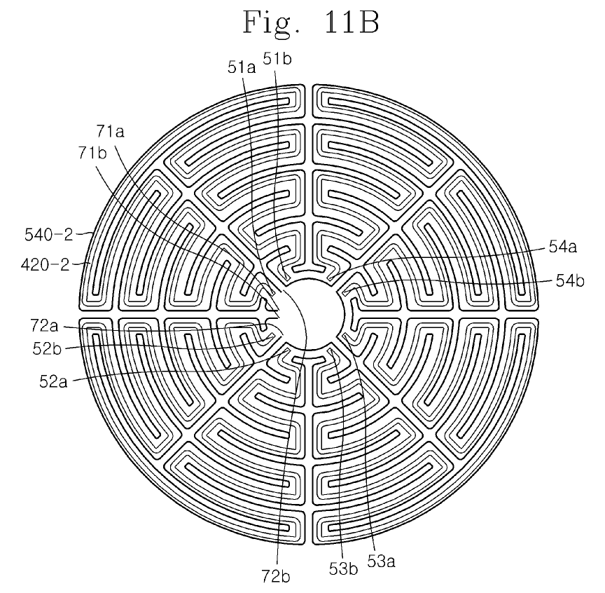

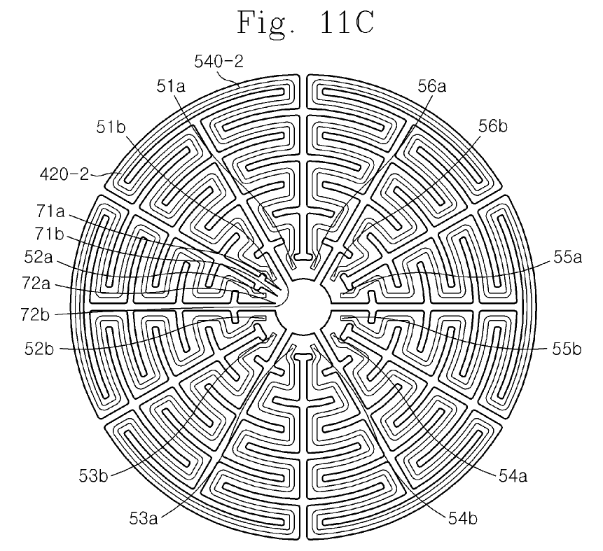

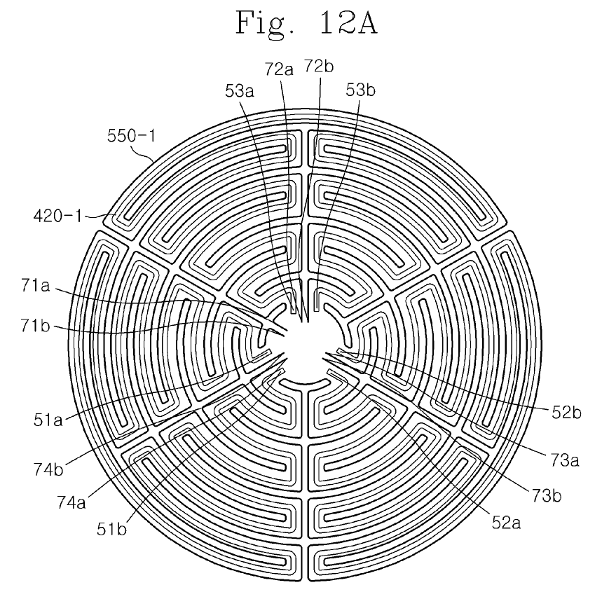

FIGS. 11A-11C are plan views of embodiments combining the multi-zone main heating elements 420-1, 420-2, and 420-3 in FIG. 4B and the multi-zone auxiliary heating elements 540-1, 540-2, and 540-3 in FIG. 6B. That is, respective embodiments here represent a combination of 420-1 and 540-1 for three sections, a combination of 420-2 and 540-2 for four sections, and a combination of 420-3 and 540-3 for six sections, respectively.

Referring to FIGS. 11A-11C, the multi-zone main heating elements 420-1, 420-2, and 420-3 and the multi-zone auxiliary heating elements 540-1, 540-2, and 540-3 are disposed without overlapping each other between layers throughout the insulating plate 110.

The multi-zone main heating element 420-1 includes a pattern in which predetermined ends 51a and 51b, 52a and 52b, and 53a and 53b are connected to different terminal pairs, respectively, to form a plurality of heating zones dividing the insulating plate 110. The multi-zone main heating element 420-2 includes predetermined ends 51a and 51b, 52a and 52b, 53a and 53b, and 54a and 54b connected to different terminal pairs, respectively. The multi-zone main heating element 420-3 includes predetermined ends 51a and 51b, 52a and 52b, 53a and 53b, 54a and 54b, 55a and 55b, and 56a and 56b connected to different terminal pairs, respectively.

The multi-zone auxiliary heating element 540-1 includes a pattern in which predetermined ends 71a and 71b, and 72a and 72b are connected to different terminal pairs (2 pairs), respectively, to form a plurality of heating zones dividing the insulating plate 110. The multi-zone auxiliary heating element 540-2 includes predetermined ends 71a and 71b, and 72a and 72b connected to different terminal pairs (2 pairs), respectively. The multi-zone auxiliary heating element 540-3 includes predetermined ends 71a and 71b, and 72a and 72b connected to different terminal pairs (2 pairs), respectively.

In FIG. 11A, the multi-zone main heating element 420-1 includes three identical repetitive patterns arranged separately along the circumference in the three sections. In addition, the multi-zone auxiliary heating element 540-1 includes patterns corresponding to the three repetitive patterns of the multi-zone main heating element 420-1.

In FIG. 11B, the multi-zone main heating element 420-2 includes four identical repetitive patterns arranged separately along the circumference in the four sections. In addition, the multi-zone auxiliary heating element 540-2 includes patterns corresponding to the four repetitive patterns of the multi-zone main heating element 420-2.

In FIG. 11C, the multi-zone main heating element 420-3 includes six identical repetitive patterns arranged separately along the circumference in the six sections. In addition, the multi-zone auxiliary heating element 540-3 includes patterns corresponding to the six repetitive patterns of the multi-zone main heating element 420-3.

FIGS. 11A-11C show structures in which the outermost arc portion of the pattern of the multi-zone main heating element 420-1, 420-2, or 420-3 is positioned further inward such that the pattern of the multi-zone auxiliary heating element 540-1, 540-2, or 540-3 surrounds the outermost arc portion of the pattern of the multi-zone main heating element 420-1, 420-2, or 420-3. More specifically, the pattern of the multi-zone auxiliary heating element 540-1, 540-2, or 540-3 includes predetermined ends 71a and 71b, and 72a and 72b connected to different terminal pairs (2 pairs), respectively, and the pattern connected to the ends 71a and 71b is such that the repetitive patterns are interconnected to surround the outermost arc portion of the multi-zone main heating element 420-1, 420-2, or 420-3, and the pattern connected to the ends 72a and 72b is such that the repetitive patterns are interconnected to be disposed in the remaining space between the multi-zone main heating elements 420-1, 420-2, and 420-3 so as to fill the same. Since there is no vertical overlap between the patterns of the multi-zone main heating elements 420-1, 420-2, and 420-3 and the patterns of the multi-zone auxiliary heating elements 540-1, 540-2, and 540-3, there is no risk of generating hot zones. The respective patterns of the multi-zone main heating elements 420-1, 420-2, and 420-3 and the auxiliary heating elements 540-1, 540-2, and 540-3 do not have non-heating straight sections, unlike conventional heating elements. Furthermore, the pattern of the multi-zone auxiliary heating elements 540-1, 540-2, and 540-3 is a 2D wire-type resistor, which allows free and flexible arrangement without overlapping with the pattern of the multi-zone main heating elements 420-1, 420-2, and 420-3, which is a coil-type resistor, thereby compensating for temperature while being disposed between the patterns of the main heating elements 420-1, 420-2, and 420-3.

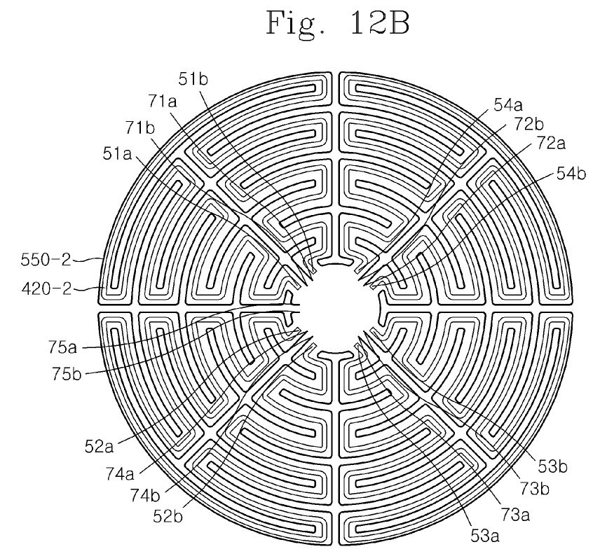

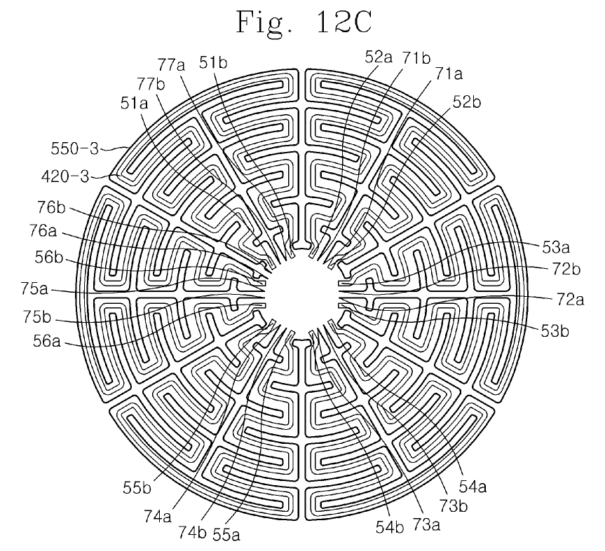

FIGS. 12A-12C are plan views of embodiments combining the multi-zone main heating elements 420-1, 420-2, and 420-3 in FIG. 4B and the multi-zone auxiliary heating elements 550-1, 550-2, and 550-3 in FIG. 6C. That is, respective embodiments here represent a combination of 420-1 and 550-1 for three sections, a combination of 420-2 and 550-2 for four sections, and a combination of 420-3 and 550-3 for six sections, respectively.

Referring to FIGS. 12A-12C, the multi-zone main heating elements 420-1, 420-2, and 420-3 and the multi-zone auxiliary heating elements 550-1, 550-2, and 550-3 are disposed without overlapping each other between layers across the entire insulating plate 110.

The multi-zone main heating element 420-1 includes a pattern in which predetermined ends 51a and 51b, 52a and 52b, and 53a and 53b are connected to different terminal pairs, respectively, to form a plurality of heating zones dividing the insulating plate 110. The multi-zone main heating element 420-2 includes predetermined ends 51a and 51b, 52a and 52b, 53a and 53b, and 54a and 54b connected to different terminal pairs, respectively. The multi-zone main heating element 420-3 includes predetermined ends 51a and 51b, 52a and 52b, 53a and 53b, 54a and 54b, 55a and 55b, and 56a and 56b connected to different terminal pairs, respectively.

The multi-zone auxiliary heating element 550-1 includes a pattern in which predetermined ends 71a and 71b, 72a and 72b, 73a and 73b, and 74a and 74b are connected to different terminal pairs (4 pairs), respectively, to form a plurality of heating zones dividing the insulating plate 110. The multi-zone auxiliary heating element 550-2 includes predetermined ends 71a and 71b, 72a and 72b, 73a and 73b, 74a and 74b, and 75a and 75b connected to different terminal pairs (5 pairs), respectively. The multi-zone auxiliary heating element 550-3 includes predetermined ends 71a and 71b, 72a and 72b, 73a and 73b, 74a and 74b, 75a and 75b, 76a and 76b, and 77a and 77b connected to different terminal pairs (7 pairs), respectively.

In FIG. 12A, the multi-zone main heating element 420-1 includes three identical repetitive patterns arranged separately along the circumference in the three sections. Furthermore, the multi-zone auxiliary heating element 550-1 includes patterns corresponding to the three identical repetitive patterns of the multi-zone main heating element 420-1.

In FIG. 12B, the multi-zone main heating element 420-2 includes four identical repetitive patterns arranged separately along the circumference in the four sections. In addition, the multi-zone auxiliary heating element 550-2 includes patterns corresponding to the four repetitive patterns of the multi-zone main heating element 420-2.

In FIG. 12C, the multi-zone main heating element 420-3 includes six identical repetitive patterns arranged separately along the circumference in the six sections. In addition, the multi-zone auxiliary heating element 550-3 includes patterns corresponding to the six repetitive patterns of the multi-zone main heating element 420-3.

FIGS. 12A-12C show structures in which the outermost arc portion of the pattern of the multi-zone main heating element 420-1, 420-2, or 420-3 is positioned further inward such that the pattern of the multi-zone auxiliary heating element 550-1, 550-2, or 550-3 surrounds the outermost arc portion of the pattern of the multi-zone main heating element 420-1, 420-2, or 420-3. More specifically, in the pattern of the multi-zone auxiliary heating element 550-1, 550-2, or 550-3, the pattern connected to the ends 71a and 71b is such that the repetitive patterns are interconnected to surround the outermost arc portion of the multi-zone main heating element 420-1, 420-2, or 420-3, and the pattern connected to the remaining ends 72a and 72b, 73a and 73b, 74a and 74b, 75a and 75b, and 76a and 77b is such that the repetitive patterns are disposed in the remaining space between the multi-zone main heating elements 420-1, 420-2, and 420-3 so as to fill the same. Since there is no vertical overlap between the patterns of the multi-zone main heating elements 420-1, 420-2, and 420-3 and the patterns of the multi-zone auxiliary heating elements 550-1, 550-2, and 550-3, there is no risk of generating hot zones. The respective patterns of the multi-zone main heating elements 420-1, 420-2, and 420-3 and the auxiliary heating elements 550-1, 550-2, and 550-3 do not have non-heating straight sections, unlike conventional heating elements. Furthermore, the pattern of the multi-zone auxiliary heating elements 550-1, 550-2, and 550-3 is a 2D wire-type resistor, which allows free and flexible arrangement without overlapping with the pattern of the multi-zone main heating elements 420-1, 420-2, and 420-3, which is a coil-type resistor, thereby compensating for temperature while being disposed between the patterns of the main heating elements 420-1, 420-2, and 420-3.

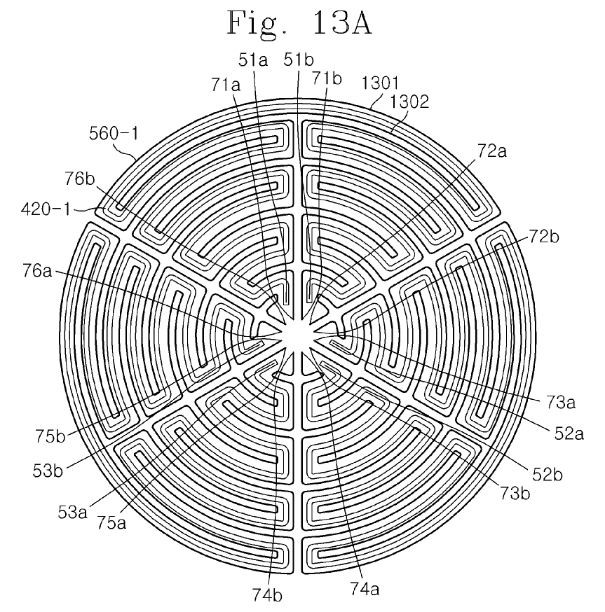

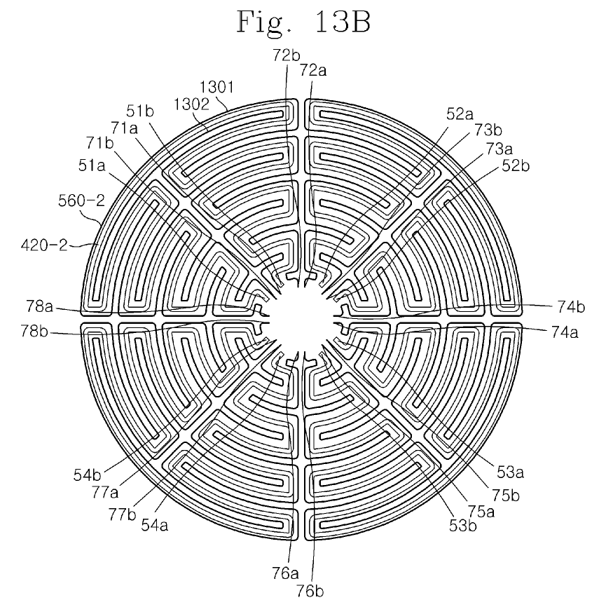

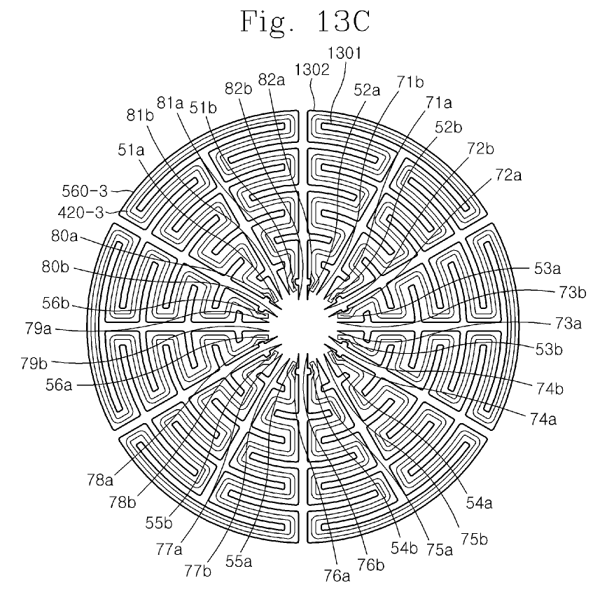

FIGS. 13A-13C are plan views of embodiments combining the multi-zone main heating elements 420-1, 420-2, and 420-3 in FIG. 4B and the multi-zone auxiliary heating elements 560-1, 560-2, and 560-3 in FIG. 6D. That is, respective embodiments here represent a combination of 420-1 and 560-1 for three sections, a combination of 420-2 and 560-2 for four sections, and a combination of 420-3 and 560-3 for six sections, respectively.

Referring to FIGS. 13A-13C, the multi-zone main heating elements 420-1, 420-2, and 420-3 and the multi-zone auxiliary heating elements 550-1, 550-2, and 550-3 are disposed without overlapping each other between layers across the entire insulating plate 110.

The multi-zone main heating element 420-1 includes a pattern in which predetermined ends 51a and 51b, 52a and 52b, and 53a and 53b are connected to different terminal pairs, respectively, to form a plurality of heating zones dividing the insulating plate 110. The multi-zone main heating element 420-2 includes predetermined ends 51a and 51b, 52a and 52b, 53a and 53b, and 54a and 54b connected to different terminal pairs, respectively. The multi-zone main heating element 420-3 includes predetermined ends 51a and 51b, 52a and 52b, 53a and 53b, 54a and 54b, 55a and 55b, and 56a and 56b connected to different terminal pairs, respectively.

The multi-zone auxiliary heating element 560-1 includes a pattern in which predetermined ends 71a and 71b, 72a and 72b, 73a and 73b, 74a and 74b, 75a and 75b, and 76a and 76b are connected to different terminal pairs (6 pairs), respectively, to form a plurality of heating zones dividing the insulating plate 110. The multi-zone auxiliary heating element 560-2 includes predetermined ends 71a and 71b, 72a and 72b, 73a and 73b, 74a and 74b, 75a and 75b, 76a and 76b, 77a and 77b, and 78a and 78b connected to different terminal pairs (8 pairs), respectively. The multi-zone auxiliary heating element 560-3 includes predetermined ends 71a and 71b, 72a and 72b, 73a and 73b, 74a and 74b, 75a and 75b, 76a and 76b, 77a and 77b, 78a and 78b, 79a and 79b, 80a and 80b, 81a and 81b, and 82a and 82b connected to different terminal pairs (12 pairs), respectively.

In FIG. 13A, the multi-zone main heating element 420-1 includes three identical repetitive patterns arranged separately along the circumference in the three sections. In addition, the multi-zone auxiliary heating element 560-1 includes patterns corresponding to the three repetitive patterns of the multi-zone main heating element 420-1.

In FIG. 13B, the multi-zone main heating element 420-2 includes four identical repetitive patterns arranged separately along the circumference in the four sections. In addition, the multi-zone auxiliary heating element 560-2 includes patterns corresponding to the four repetitive patterns of the multi-zone main heating element 420-2.

In FIG. 13C, the multi-zone main heating element 420-3 includes six identical repetitive patterns arranged separately along the circumference in the six sections. In addition, the multi-zone auxiliary heating element 560-3 includes patterns corresponding to the six repetitive patterns of the multi-zone main heating element 420-3.

FIGS. 13A-13C show structures in which the outermost arc portion of the pattern of the multi-zone main heating element 420-1, 420-2, or 420-3 is positioned further inward such that the pattern of the multi-zone auxiliary heating element 560-1, 560-2, or 560-3 surrounds the outermost arc portion of the pattern of the multi-zone main heating element 420-1, 420-2, or 420-3. More specifically, the patterns of the multi-zone auxiliary heating elements 560-1, 560-2, and 560-3 include a pattern 1301 that surrounds the outermost arc portion of the pattern of the multi-zone main heating element 420-1, 420-2, or 420-3 in each zone of the multi-zone main heating elements 420-1, 420-2, and 420-3, and a pattern 1302 that is positioned between the patterns of the multi-zone main heating elements 420-1, 420-2, and 420-3 on the inner side and fills the same. Since there is no vertical overlap between the patterns of the multi-zone main heating elements 420-1, 420-2, and 420-3 and the patterns of the multi-zone auxiliary heating elements 560-1, 560-2, and 560-3, there is no risk of generating hot zones. The respective patterns of the multi-zone main heating elements 420-1, 420-2, and 420-3 and the auxiliary heating elements 560-1, 560-2, and 560-3 do not have non-heating straight sections, unlike conventional heating elements. Furthermore, the pattern of the multi-zone auxiliary heating elements 560-1, 560-2, and 560-3 is a 2D wire-type resistor, which allows free and flexible arrangement without overlapping with the pattern of the multi-zone main heating elements 420-1, 420-2, and 420-3, which is a coil-type resistor, thereby compensating for temperature while being disposed between the patterns of the main heating elements 420-1, 420-2, and 420-3.

As described above, a susceptor 100 according to an embodiment of the present disclosure may configure a stacked structure in which a coil-type resistor as a main heating element 112-2 and a 2D wire-type resistor as an auxiliary heating element 112-1 are stacked in layers, thereby reducing the heat transfer distance and increasing the amount of heat transfer to the upper surface, and the main heating element 112-2 and the auxiliary heating element 112-1 in respective stacked layers are densely interspersed without overlapping each other, thereby improving temperature uniformity across the entire area of the upper surface of the susceptor 100.

Furthermore, the susceptor 100 of the present disclosure, compared to the conventional heating elements that have limited spacing control, may provide a uniform temperature distribution across the upper surface of the susceptor without generation of a cool zone in the empty space between the heating elements even when the heating elements are freely arranged. Furthermore, since the radially straight connection lines of the conventional heating element pattern are eliminated, and there is no overlap between the main heating element 112-2 and the auxiliary heating element 112-1, the hot zone may not be formed.

In addition, according to the susceptor 100 of the present disclosure, the auxiliary heating element 112-1 in the form of a 2D wire has a thin and fine line width and is easy to deform, so it has a high degree of wiring freedom and may be appropriately applied to areas requiring temperature compensation. Furthermore, when the auxiliary heating element 112-1 is selected in a form that goes around the outer side of the main heating element 112-2, it may also be easy to compensate for the temperature of the edge portion, which is a relatively low-heat area.

As described above, in the present disclosure, although specific details, such as detailed components, have been described based on limited embodiments and drawings, these are provided merely to facilitate a more comprehensive understanding of the present disclosure, and the present disclosure is not limited to the above embodiments. Those skilled in the art to which the present disclosure pertains may make various modifications and variations without departing from the essential features of the present disclosure. Therefore, the idea of the present disclosure should not be limited to the described embodiments, and all technical ideas that are identical or equivalent to the claims described below, as well as the claims, should be construed as being included within the scope of the present disclosure.

What is claimed is:

1. A susceptor comprising an insulating plate comprising a main heating element of a first layer and an auxiliary heating element of a second layer, which are stacked,
wherein the main heating element is formed as a coil-type resistor connected between each of one or more first terminal pairs, the coil-type resistor being configured as a resistor wire wound in a coil shape within the insulating plate, and the main heating element comprises first arc portions at different radial positions and first folded portions connected between the first arc portions,
wherein the auxiliary heating element is formed as a 2D wire-type resistor connected between each of one or more second terminal pairs, the 2D wire-type resistor being configured as a resistor wire disposed on a plane within the insulating plate, and the auxiliary heating element comprises second arc portions at different radial positions and second folded portions connected between the second arc portions, and
wherein the main heating element and the auxiliary heating element are arranged without overlapping each other between layers across the insulating plate.

2. The susceptor of claim 1,
wherein the main heating element is disposed above or below the auxiliary heating element.

3. The susceptor of claim 1,
wherein the main heating element comprises a first pattern connected to two terminals of one of the first terminal pairs to form a single main heating zone across the insulating plate, and
wherein the auxiliary heating element comprises a second pattern connected to two terminals of one of the second terminal pairs to form a single compensation heating zone across the insulating plate.

4. The susceptor of claim 3,
wherein the first pattern comprises three, four, or six first repetitive patterns arranged continuously along a circumference, and the second pattern comprises a second repetitive pattern corresponding to the first repetitive pattern, the second repetitive pattern being continuous.

5. The susceptor of claim 1,
wherein the main heating element comprises respective first patterns connected to a plurality of the first terminal pairs, the first patterns forming a plurality of main heating zones dividing the insulating plate, and
wherein the auxiliary heating element comprises a second pattern connected to two terminals of one of the second terminal pairs to form a single compensation heating zone across the insulating plate.

6. The susceptor of claim 5,
wherein the first pattern comprises three, four, or six first repetitive patterns arranged separately along a circumference, and the second pattern comprises a second repetitive pattern corresponding to the first repetitive patterns, the second repetitive pattern being continuous.

7. The susceptor of claim 5,
wherein an outermost arc portion of the first patterns is disposed further inward than an outermost arc portion of the second patterns.

8. The susceptor of claim 5,
wherein an outermost arc portion of the first patterns is disposed further outward than an outermost arc portion of the second pattern.

9. The susceptor of claim 1,
wherein the main heating element comprises respective first patterns connected to a plurality of the first terminal pairs, the first patterns forming a plurality of main heating zones dividing the insulating plate, and
wherein the auxiliary heating element comprises respective second patterns connected to a plurality of the second terminal pairs, the second patterns forming a plurality of compensation heating zones dividing the insulating plate.

10. The susceptor of claim 9,
wherein the main heating element comprises three first repetitive patterns for three of the plurality of main heating zones, the three first repetitive patterns being arranged separately along a circumference, and
wherein the auxiliary heating element comprises second repetitive patterns for the plurality of compensation heating zones, the second repetitive patterns corresponding to the first repetitive patterns.

11. The susceptor of claim 9,
wherein the main heating element comprises four first repetitive patterns for four of the plurality of main heating zones, the four first repetitive patterns being arranged separately along a circumference, and
wherein the auxiliary heating element comprises second repetitive patterns for the plurality of compensation heating zones, the second repetitive patterns corresponding to the first repetitive patterns.

12. The susceptor of claim 9,
wherein the main heating element comprises six first repetitive patterns for six of the plurality of main heating zones, the six first repetitive patterns being arranged separately along a circumference, and
wherein the auxiliary heating element comprises second repetitive patterns for the plurality of compensation heating zones, the second repetitive patterns corresponding to the first repetitive patterns.
